(19) United States
(12) Patent Application Publication
(10) Pub. No.: US 2025/0174594 A1
(43) Pub. Date: May 29, 2025

(54) System and Method for Aligning Bonding Pads with Bonding Locations using Moiré Patterns

(71) Applicant: CANON KABUSHIKI KAISHA, Tokyo (JP)

(72) Inventors: Dwayne L. LaBrake, Cedar Park, TX (US); Niyaz Khusnatdinov, Round Rock, TX (US)

(21) Appl. No.: 18/523,243

(22) Filed: Nov. 29, 2023

(51) Int. Cl. H01L 23/00; G05B 19/402; H01L 21/67

(52) U.S. Cl. CPC H01L 24/80; G05B 19/402; H01L 21/67144; G05B 2219/45026; G05B 2219/49299; H01L 2224/80132

(57) ABSTRACT

A system and method for holding a chip on a chip chuck. The chip has a set of interconnect contacts. The system and method includes positioning a first grating relative to the set of interconnect contacts. The system and method includes measuring a first moiré pattern of the first grating and the set of interconnect contacts. The system and method includes adjusting position of the chip chuck relative to a substrate chuck based on the first moiré pattern.

### BACKGROUND OF INVENTION

### Technical Field

The present disclosure relates to systems and methods of aligning bonding pads with bonding locations. In particular, the present disclosure relates to systems and methods of adjusting an alignment system based on the component that is to be aligned.

### Description of the Related Art

The manufacture of devices (such as electronic devices) that include multiple components requires that these multiple components be bonded together. One method of bonding these components includes aligning a first set of electrical pads (interconnect contacts) on a first device with a second set of electrical pads with a second device. It is preferential that the systems and methods that do this alignment have an accuracy that is a fraction ( 1/10 to ¼) of the pad diameters. It is also preferential that this alignment be performed at a very high speed (less than a second or even much faster). Current methods of accomplishing this task include using alignment features on the devices to be bonded.

In recent times the size of the devices and pads are decreasing while the density of the pads is also increasing. What is needed is a fast and accurate method of aligning pads without alignment features.

### SUMMARY OF THE INVENTION

A first embodiment, may be a method. The method can include holding a chip on a chip chuck. The chip has a set of interconnect contacts. The method can include positioning a first grating relative to the set of interconnect contacts. The method can include measuring a first moiré pattern of the first grating and the set of interconnect contacts. The method can include adjusting position of the chip chuck relative to a substrate chuck based on the first moiré pattern.

In an aspect of the first embodiment the first grating can have a grating pitch that is different from a contact pitch of the set of interconnect contacts.

The first embodiment, may further comprise receiving contact arrangement information about the set of interconnect contacts. The first embodiment, can also comprise selecting the first grating from a group of gratings with different pitches based on the contact arrangement information.

In an aspect of the first embodiment selecting the grating can include determining a lattice type of the set of interconnect contacts based on the contact arrangement information. Selecting the grating can include determining two measurement directions based on the lattice type. Selecting the grating can include determining two contact pad pitches, each contact pad pitch based on distances between neighboring contact pads in a measurement direction from among the two measurement directions.

In an aspect of the first embodiment, the two measurement directions can be orthogonal to each other.

In an aspect of the first embodiment, the lattice type is rectangular and one of the two measurement directions is an inverse tangent of a ratio of contact pad pitches in each lattice direction of the set of interconnect contacts.

In an aspect of the first embodiment, wherein the lattice type is oblique and a measurement the measurement direction can be parallel to a lattice direction of the set of interconnect contacts.

In an aspect of the first embodiment, measuring the first moiré pattern can comprise illuminating the first grating at an angle relative to a plane of the first grating in a direction that is parallel to rulings of the first grating with measurement radiation. Measuring the first moiré pattern can further comprise measuring the measurement radiation that has diffracted off the set of interconnect contacts.

In an aspect of the first embodiment, positioning a grating can comprise orienting rulings of the first grating relative to set of interconnect contacts based on a lattice type of the set of interconnect contacts.

In an aspect of the first embodiment, adjusting the position of the chip chuck can comprise sending an instruction to a chip chuck stage to adjust the position of chip chuck relative to the substrate chuck.

The first embodiment, may further comprise positioning a substrate grating relative to the substrate chuck holding a substrate. The substrate has a second set of interconnect contacts. The first embodiment, may further comprise measuring a substrate moiré pattern of the substrate grating and the substrate set of interconnect contacts. The position of the chip chuck can be adjusted based on both the moiré pattern and the substrate moiré pattern.

In an aspect of the first embodiment, the first grating can be identical to the substrate grating.

The first embodiment, may further comprise positioning a second grating relative to the set of interconnect contacts. A first set of rulings of the first grating are oriented in a different direction than a second set of rulings of the second grating. The first embodiment, may further comprise measuring a second moiré pattern of the second grating and the set of interconnect contacts. The adjusting position of the chip chuck relative to the substrate chuck is based on the first moiré pattern and the second moiré pattern.

The first embodiment, may further comprise bonding the chip to product substrate. The first embodiment, may further comprise processing the substrate to manufacture a plurality of articles.

In an aspect of the first embodiment, the measuring and the adjusting are done repeatedly until the set of interconnect contacts are in a desired position based on the first moiré pattern.

A second embodiment, may be a bonding system controller. The bonding system controller can be adapted to send instructions to a chip chuck to hold a chip. The chip has a set of interconnect pads. The bonding system controller can be adapted to send instructions to a grating positioning system configured to position a first grating relative to the set of interconnect contacts. The bonding system controller can be adapted to receive a first moiré pattern of the first grating and the set of interconnect contacts from a measurement system. The bonding system controller can be adapted to send instruction of a chip chuck positioning system configured to adjust the position of the chip chuck relative to the wafer chuck based on the first moiré pattern.

A Third embodiment, may be a bonding system for bonding a chip that has a set of interconnect contacts to a substrate comprising a chip chuck configured to hold the chip. The bonding system may further comprise a wafer chuck configured to hold the substrate. The bonding system may further comprise a grating positioning system configured to position a first grating relative to the set of interconnect contacts. The bonding system may further comprise a measuring system configured to measure a first moiré pattern of the first grating and the set of interconnect contacts. The bonding system may further comprise a chip chuck positioning system configured to adjust the position of the chip chuck relative to the wafer chuck.

In an aspect of the third embodiment, the chip chuck positioning system can be further configured to bring the chip into contact with the substrate.

The third embodiment, may further comprise a plurality of gratings with different pitches. The third embodiment may also comprise a selection tool for selecting one of the plurality of gratings based on a pitch of the set of interconnect contacts.

The third embodiment, may further comprise a measurement positioning system configured to adjust positions of one or both of an illumination system and a measurement system based on arrangement information of the set of interconnect contacts.

These and other objects, features, and advantages of the present disclosure will become apparent upon reading the following detailed description of exemplary embodiments of the present disclosure, when taken in conjunction with the appended drawings.

### BRIEF DESCRIPTION OF THE FIGURES

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention and are therefore not to be considered limiting of its scope, for the invention may admit to other equally effective embodiments.

FIG. 1 is an illustration of an exemplary bonding system which in which an embodiment may be used.

FIGS. 2A-B are illustrations of an exemplary bonding head that may be used in an embodiment.

FIG. 3A is an illustration of a chip on a bonding head along with upward facing alignment system as may be used in an embodiment.

FIGS. 3B-D are illustrations of grating sets and a chip on a bonding head as may be used in an embodiment.

FIG. 3E is an illustration of a measurement light, a portion of interconnect contacts and a portion of a grating as may be used in an embodiment.

FIG. 3F is an illustration of grating set and a substrate on a substrate chuck as may be used in an embodiment.

FIG. 3G includes a graph showing a relationship between pitches of the gratings, the contact pitch and moiré pitches.

FIGS. 4A-D are illustrations of lattice types of interconnect contacts as used in an embodiment.

FIG. 5A is a flowchart illustrating a bonding method as may be used in an embodiment.

FIG. 5B is a flowchart illustrating an alignment method as may be used in an embodiment.

FIGS. 6A-C are illustrations of portions of the interconnect contacts as may be used in an embodiment.

FIGS. 7A-B are illustrations of gratings and interconnect contacts as may used in an embodiment.

FIG. 8 includes graphs showing a relationship between the range of pitches of the gratings and the contact pitch.

Throughout the figures, the same reference numerals and characters, unless otherwise stated, are used to denote like features, elements, components, or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure.

### DETAILED DESCRIPTION

The following describes certain explanatory embodiments. Other embodiments may include alternatives, equivalents, and modifications. Additionally, the explanatory embodiments may include several features, and a particular feature may not be essential to some embodiments of the devices, systems, and methods. Furthermore, some embodiments may include features from two or more of the following explanatory embodiments.

As used herein, the conjunction “or” generally refers to an inclusive “or,” though “or” may refer to an exclusive “or” if expressly indicated or if the context indicates that the “or” must be an exclusive “or.” And, as used herein, the terms “first,” “second,” and so on, do not necessarily denote any ordinal, sequential, or priority relation and may be used to more clearly distinguish one member, operation, element, group, collection, set, etc. from another without expressing any ordinal, sequential, or priority relation.

### Bonding System

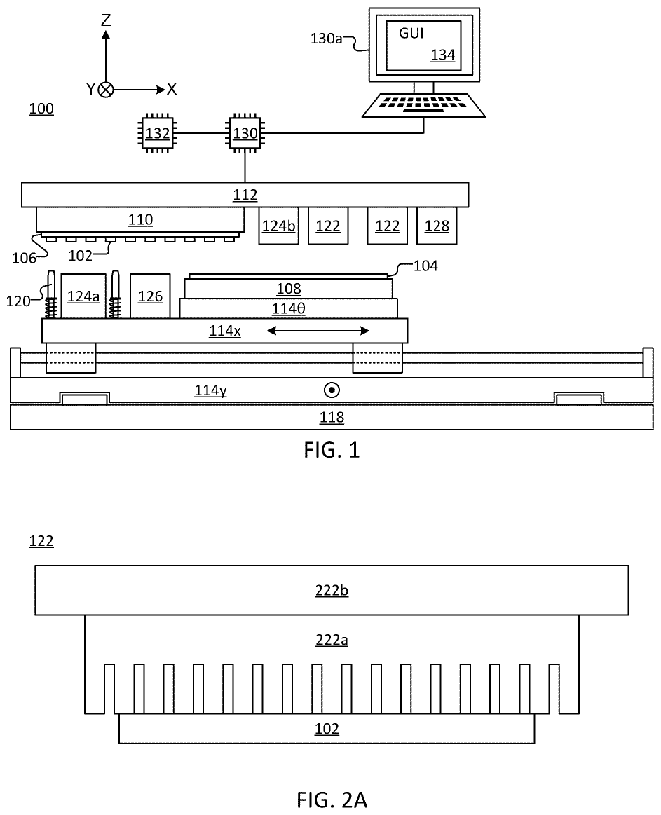

FIG. 1 is an illustration of some components of a bonding system 100 which may be used to bond a chip 102 to a substrate 104. The chip 102 is a component that includes a chip set of interconnect contacts 105a. The chip may have widths and heights on the order 0.5 mm to 15 mm and a thickness between 10-800 μm. The substrate 104 also includes a substrate set of interconnect contacts 105b. The chip set of interconnect contacts 105a and the substrate set of interconnect contacts 105b will in general be referred to as interconnect contacts 105 which provide a plurality of connections between the chip 102 and the substrate 104. In an embodiment, these plurality of interconnect contacts 105 provide electrical connections between the chip 102 and the substrate 104. In an alternative embodiment, the plurality of interconnect contacts 105 provide one or more of fluid connections, optical connections, and electrical connections. During the bonding process it is very important that the chip set interconnect contacts 105a and the substrate set of interconnect contacts 105b be aligned with each other. This becomes increasingly difficult as the size of each interconnect contact 105 and the density of the plurality of interconnect contacts 105 increases. Each interconnect contact 105 may be made of an electrically conductive material such as copper. Each interconnect contact 105 may be flush with the surface of the chip 102 or substrate 104 or dished nanometers below the surface of the chip 102 or substrate 104. The surface of the chip 102 or substrate 104 may be a dielectric material such as silicon oxide or silicon nitride with interconnect contacts 105 dished nanometers below the plane of the dielectric.

In an embodiment, the chip 102 may have a small geometric shape (for example a rectangle or other polygon) and may have a planar dimension that is between 0.5 mm to 30 mm and may have a thickness of less than 1 mm (for example 0.8 to 0.01 mm). The chip 102 may have been singulated from a larger substrate such as a semiconductor wafer, which may have been subjected to a thinning process. The chip 102 will typically carry a set of integrated electronic components and circuits formed on it by patterning, coating, etching, doping, plating, singulating, etc. The chip 102 will typically have electrical functions such as: memory, logic, field programmable gate arrays (FPGA), accelerator circuits, application-specific integrated circuits (ASICs), security co-processors, graphics processing units (GPUS), machine learning circuits, specialized processors, controllers, devices, electrical circuits, arrays of passive components, etc. The chip 102 may also be a MEMS device, an optical device, an electrical-optical device, etc. The chip 102 may be any device that has a set of interconnect contacts 105a.

In an embodiment the substrate 104 is a patterned semiconductor wafer that has a substrate set of interconnect contacts 105b. The substrate set of interconnect contacts 105b may provide connections to components within the substrate 104 or mounted onto the substrate 104. The substrate 104 may have a plurality of bonding locations for the chip 102 and also for other chips different from the chip 102. The substrate 104 may already have chips that are identical and/or different from chip 102 bonded to the substrate 104. The substrate set of interconnect contacts 105b may be on a chip bonded to the substrate 104. In an alternative embodiment, the substrate 104 is not a patterned semiconductor wafer but does have a substrate set of interconnect contacts 105b.

FIG. 1 illustrates a plurality of chips 102 temporarily attached to a transfer substrate 106. The substrate 104 is held by a substrate chuck 108. The transfer substrate 106 is held by a transfer chuck 110. In an embodiment, the transfer chuck 110 is mounted to a bridge 112 opposite the substrate chuck 110. In an alternative embodiment, the transfer chuck 110 is mounted adjacent to the substrate chuck 110. In an embodiment, the transfer substrate 106 is a tape frame and the transfer chuck 110 is adapted for mounting a tape frame and helping with the release of the chip 102 from the tape frame. In an alternative embodiment, the transfer substrate is a reel on which the chip 102 is mounted and the transfer chuck 110 is a reel feeder. In an alternative embodiment, the transfer substrate 106 is a tray with pockets for holding the chip 102 in each pocket and the transfer chuck 110 is a tray holder.

The bonding system 100 may include or be in communication with one or more robots (not shown) for loading the transfer substrate 106 on and off the transfer chuck 110 and the substrate 104 on and off the substrate chuck 108. An example of such a robot is commonly referred to as equipment front end module (EFEM) which include robots for transferring substrates of a variety of types between ultra clean storage containers such as a front opening unified pod (FOUP).

The substrate chuck 108 may be mounted to a substrate stage 114. The substrate stage 114 may provide a single axis or multiple axis (for example 6) of motion control with mm scale to sub-mm accuracy over a limited range. The substrate stage 114 may be a highly accurate X-Y-Z-θ stage combined with a light interferometry measurement system so that the absolute position can be repeatedly achieved high accuracy. In an embodiment, the substrate stage 114 may include: a substrate rotation stage 1140; a substrate x motion stage 114x; a substrate y motion stage 114y; and possibly other stages.

The bonding system 100 may include a transfer head 120. The bonding system 100 may include a plurality of transfer heads 120 that are used in parallel. The transfer head 120 is used to transfer chips 102 to a bonding head 122. In an embodiment, the transfer head 120 may include a chip chuck that is a vacuum type suction nozzle that can be moved in at least the direction towards the transfer chuck 110 by one or more actuators. The tip of the suction nozzle may be smaller than the chip 102. In an alternative embodiment, the transfer head 120 may include a chip chuck for holding the chip 102 which may be but is not limited to: a Bernoulli chuck; a vacuum chuck; a pin-type chuck; a groove-type chuck; an electrostatic chuck; an electromagnetic chuck; a non-contact chuck; a PEEK plastic chuck; a suction cup; and/or the like. The transfer head 120 may include one or more actuators or stages such as voice coil motors, piezoelectric motors, linear motors, nut and screw motors, piezo-actuated stages, brushless DC motor stages, DC motor stages stepper motors, which are configured to move the chip chuck to and from the transfer substrate 106 and the bonding head 122 in for example the z-axis direction, and potentially other directions (for example x, y, θ, ψ, and φ-axes).

The bonding system 100 may include or be in communication with a chip pretreatment system(s) (not shown). The pretreatment may include wet and/or dry chemical processes which prepare the surface of the chip 102 prior to bonding the chip 102 to the substrate 104. The pretreatment of the chip 102 may occur at any time prior to bonding the chip 102 to the substrate 104. For example, the pretreatment may occur prior to the chip 102 being loaded onto the transfer substrate 106. For example, the pretreatment may occur while the chip 102 is on the transfer substrate 106. For example, the pretreatment may occur while the chip 102 is on the transfer head 120. For example, the pretreatment may occur while the chip 102 is on the bonding head 122. For example, the pretreatment may occur after the chip 102 is on the transfer head 120 and prior to the chip 102 being loaded onto the bonding head 104.

The bonding system 100 includes an upward facing alignment system 124a. The upward facing alignment system 124a may be used to measure the position of the chip 102 on the bonding head 122. The bonding system 100 also includes a downward facing alignment system 124b that is used to measure a bonding location on the substrate 104. In an alternative embodiment, the upward facing alignment system 124a and downward facing alignment system 124b may be a single system that can measure both the chip 102 on the bonding head 122 and the bonding location on the substrate 104.

The bonding system 100 may include an upward facing microscope 126 for inspecting chips 102 on the transfer substrate 106 and also inspecting chips on the bonding heads 122. The bonding system 100 may include a downward facing microscope 128 for inspecting the substrate 104.

The bonding system 100 is regulated, controlled, and/or directed by one or more processors 130 (controller) in communication with one or more components and/or subsystems such as the substrate chuck 108, the transfer chuck 110, the substrate stage 114, the transfer head 120, bonding head 122, upward facing alignment system 124a, downward facing alignment system 124b, upward facing microscope 126, downward facing microscope 128. The processor 130 may operate based on instructions in a computer readable program stored in a non-transitory computer readable memory 132. The memory 132 may be distributed among multiple processors. The processor 130 may be or include one or more of a CPU, MPU, GPU, ASIC, FPGA, DSP, and one or more general-purpose computers. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The processor 130 may include a plurality of processors that are both included in the bonding system 100 and in communication with the bonding system 100. The processor 130 may be in communication with a networked computer 130a on which analysis is performed and control files such as a drop pattern are generated. In an embodiment, there are one or more graphical user interface (GUI) 132 on one or both of the networked computer 140a and a display in communication with the processor 130 which are presented to an operator and/or user.

### Bonding Head

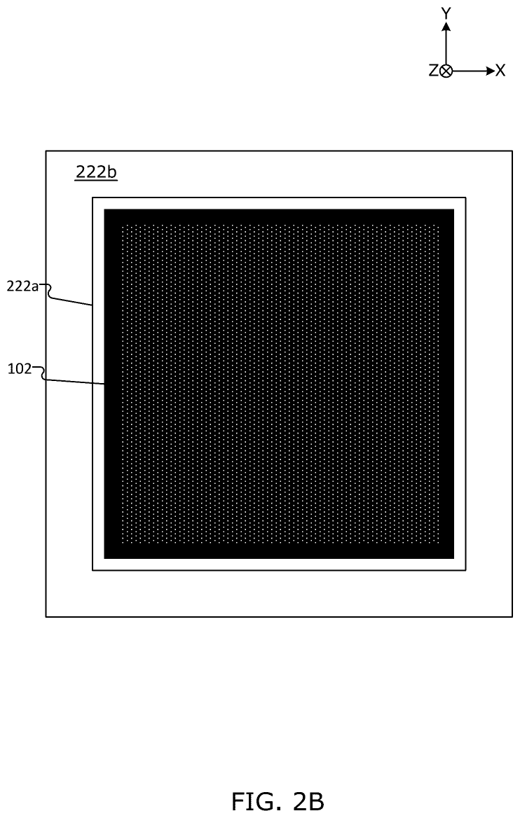

As illustrated in FIG. 1 the bonding system 100 includes a bonding head 122. The bonding head 122 may be attached to the bridge 112. The bonding system 100 may include a plurality of bonding heads 122 which are used in parallel. The bonding head 122 is positioned opposite the substrate chuck 108. Each of the bonding heads 122 includes a bonding head chip chuck 222a and may include a bonding head chip stage 222b as illustrated in FIG. 2A. The bonding head chip chuck 222a is adapted to hold the chip 102 in a stable secure manner with position stability that is less than 1 μm. The bonding head chip chuck 222a may be adapted to hold the back of the chip 102. In an alternative embodiment, the bonding head chip chuck 222a may be adapted to grip the edges of the chip 102. The bonding head chip chuck 222a may be: a vacuum chuck; a latch type chuck; an edge griping chuck; a pin-type chuck; a groove-type chuck; an electrostatic chuck; or an electromagnetic chuck.

The bonding head chip stage 222b is a motion stage for controlling the position of the bonding head chip chuck 222a relative to the bridge 112. The bonding head stage 222b provides motion control in one or more directions in for example the z-axis direction, and potentially other directions (for example x, y, θ, ψ, and φ-axes). The bonding head stage 222b may include one or more actuators or stages such as voice coil motors, piezoelectric motors, linear motors, nut and screw motors, piezo-actuated stages, brushless DC motor stages, DC stepper motors. The positioning accuracy of the bonding head stage 222b may be less than 100 nm. FIG. 2B is an illustration of a chip 102 on a bonding head chip chuck 222a showing a chip set of interconnect contacts 105a on the chip 102. As chips become more complex the number of interconnect contacts 105 increase and can be in the hundreds, thousands, tens of thousands, hundreds of thousands, even millions. The bonding head chip stage 222b may employ a highly accurate X-Y-Z-θ stage combined with a light interferometry system so that the absolute position can be repeatedly achieved with high accuracy.

### Alignment System

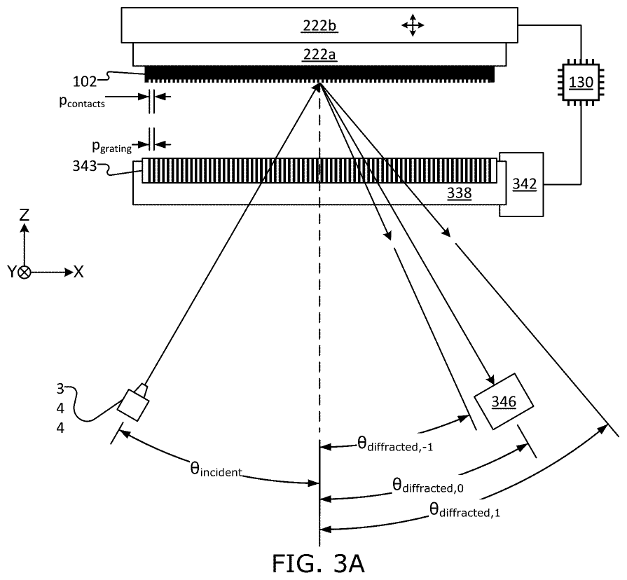

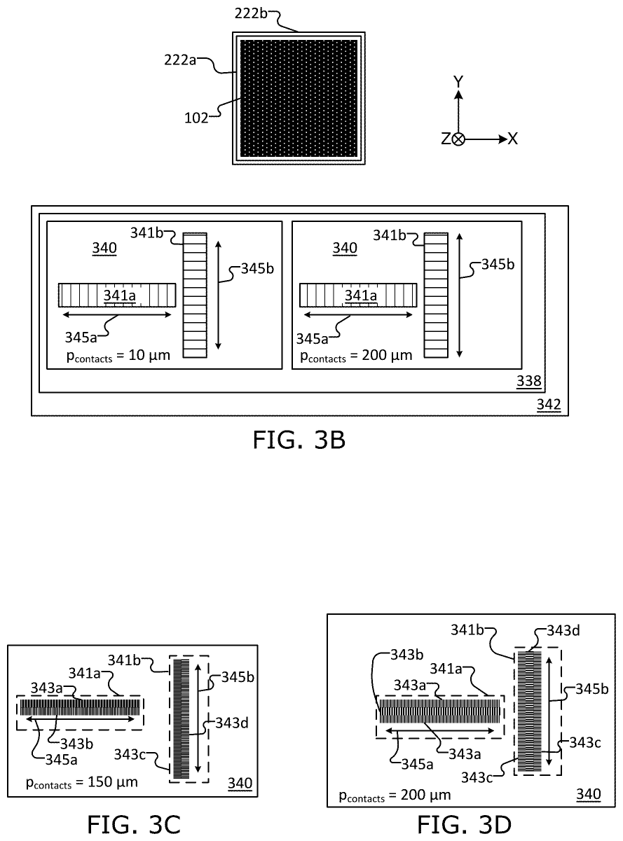

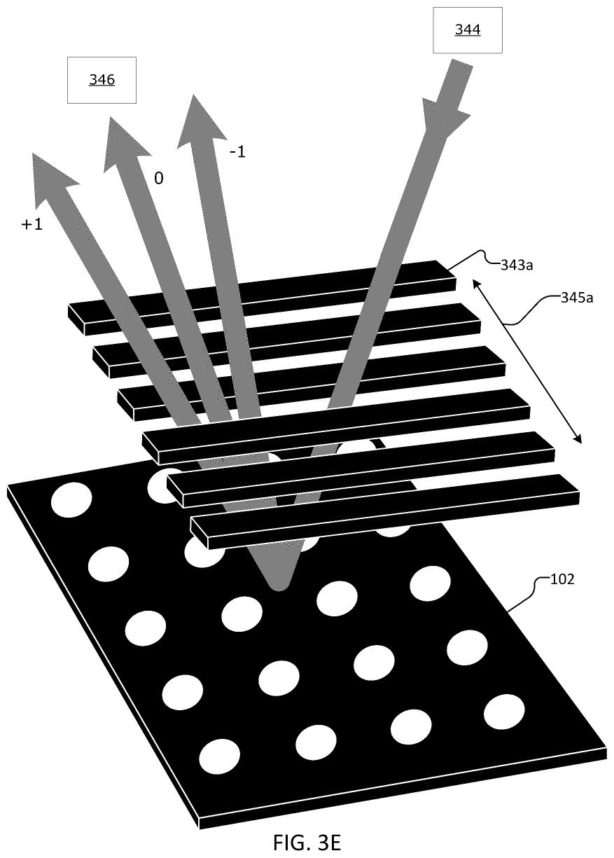

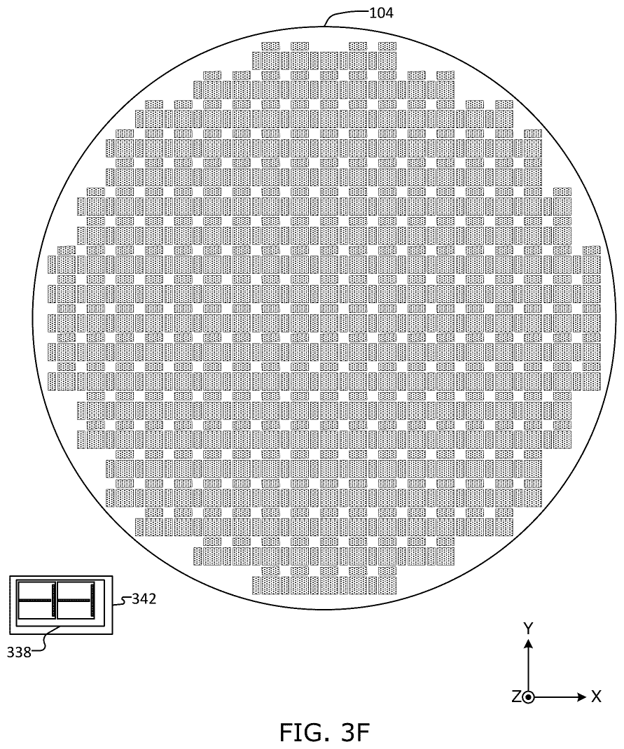

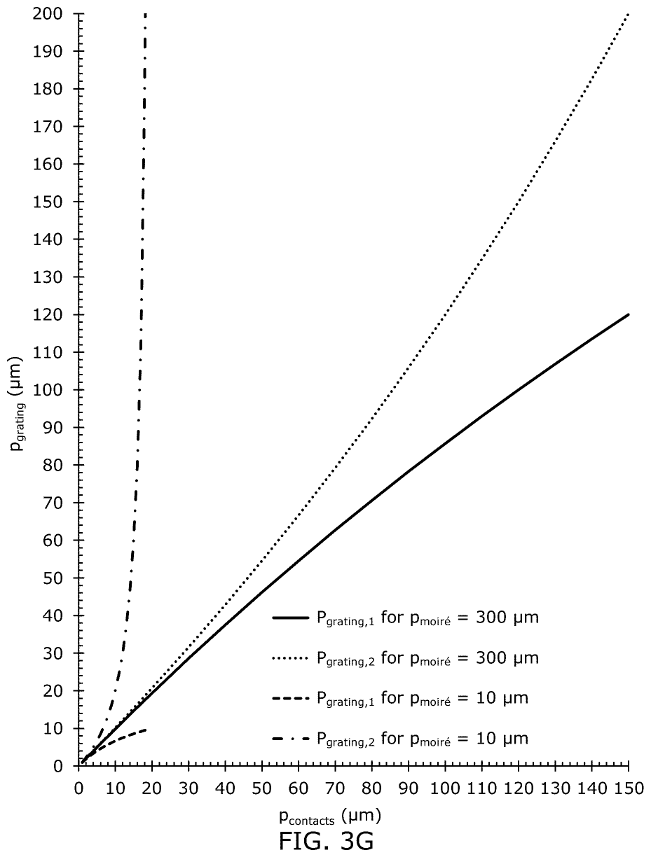

The bonding system 100 includes an alignment system 300. The upward facing alignment system 124a, the downward facing alignment system 124b, or a single alignment system that looks both up and down are all examples of the alignment system 300 which may be used in the bonding system 300. The alignment system 300 includes a grating set 340 as illustrated in FIG. 3A. Each grating set 340 is mounted on a grating set carrier 338 as illustrated in FIG. 3B. The grating set 340 includes two groups of gratings a first group of gratings 341a and a second group of gratings 341b. Each grating set is designed to work with a specific contact pitches p_{contact} of the interconnect contacts 105. Each group of gratings 341 may include rulings/slits that are oriented in a grating pitch direction 345 that is orthogonal to the other group of gratings. Orthogonal means 90°±5°. For example, the grating set 340 may include an x-direction group of gratings 341a that have slits/rulings oriented along the x axis in grating pitch direction 345a and the y-direction group of gratings 341b that have slits/rulings oriented along the y-axis in grating pitch direction 345b as illustrated in FIG. 3B. Each group of gratings includes two or more gratings. For example, each group of gratings 341 may include 2, 3, or 4 gratings as illustrated in FIGS. 3C-D. Each grating in the group of gratings have rulings/slit that are orientated in the same grating pitch direction 345. Each of the gratings in the group of gratings has a grating pitch of the rulings/slit in the same grating pitch direction 345. Each group of gratings may have at least two different grating pitches in the same grating pitch direction 345. The grating set carrier 338 includes at least one grating set including the two groups of gratings and may include additional grating sets. For example, the grating set 340 illustrated in FIG. 3C has been designed to work with p_{contacts} of 150 μm and includes an x-direction group of gratings 341a and a y-direction group of gratings 341b. The x-direction group of gratings 341a includes a first grating 343a with a first period and a second grating 343b with a second period different from the first period. The y-direction group of gratings 341b includes a third grating 343c with the first period and the fourth grating 343d with the second period. The grating set 340 illustrated in FIG. 3D has been designed to work with p_{contacts} of 200 μm and each group of gratings has 2 different pitches.

Each grating 343 in a first group of gratings 341a has rulings oriented in a first grating pitch direction 345a and each grating 343 in a second group of gratings 341b has rulings oriented in a second grating pitch direction 345b that is different than the first grating pitch direction 345a. In an embodiment, the rulings of each of the gratings 343 in the first group of gratings 341a are orthogonal to the rulings of each of the gratings in the second group of gratings 341b. The alignment system 300 includes a grating positioning system 342 that positions the grating set carrier 338 relative to the interconnect contacts 105. Each of the gratings 343 in the grating sets 340 may be a transmission grating or a reflection grating. Each of the gratings 343 in the grating sets 340 may be an absorption style grating forming a series of slits in which light passes through or is reflected from. In an alternative embodiment, each of the gratings 343 in the grating set 340 is a phase grating. A phase grating is a device that spatially modulates the phase of an electromagnetic wavefront.

The gratings 343 in the gratings sets 340 may be produced with photolithography methods or traditional grating production methods. Metals like chromium, aluminum, titanium, copper, or any other suitable metal may be used to make the line gratings on a piece of glass. The metal gratings may be coated with an oxidation protection layer like titanium, or dielectric materials like silicon dioxide, silicon nitride, magnesium fluoride, etc. The downward facing alignment system 124b also uses this same system as the upward facing alignment system to identify the positions of the substrate set of interconnect contacts 105b on a substrate 104 as illustrated in FIG. 3F.

In an embodiment, the grating positioning system 342 takes a grating set carrier 338 from a grating storage system and positions the grating set carrier 338 relative to the chip 102. The grating storage system stores multiple grating set carriers 338 each having a different pair of grating pitches p_{grating,1} and p_{grating,2}. In an alternative embodiment, the grating storage system may store multiple gratings 343 with different pitches which are then assembled into grating groups with pairs of grating pitches. The grating positioning system 342 may include a loading system for loading individual gratings onto the grating set carrier 338 or loading a different grating set carrier 338 into the alignment system 300. In an alternative embodiment, the grating set carrier 338 includes multiple grating sets 340 each with different pairs of grating pitches p_{grating,1} and p_{grating,2}. The grating positioning system 342 includes stages and/or actuators for positioning the grating set carrier 338 in at least a rotation direction that is in a plane parallel to a plane of one or more of a holding surface of the bonding head chip chuck 222a, a holding surface of the substrate chuck, and the interconnect contacts 105. The plane of the interconnect contacts 105 is parallel to a chucking surface of the bonding head chuck 222a and a chucking surface of the substrate chuck 108. The grating positioning system 342 may include a highly accurate X-Y-θ stage in a fixed position.

In an embodiment, the alignment system 300 includes an illumination source 344 that supplies light used by the alignment system. In an embodiment, the illumination source includes one or more of: a light emitting diode (LED); and a broadband light source. The illumination source 344 supplies light that is incident on each of the gratings 343 in the grating set 340 at an incident angle θ_{incident}. The illumination source 344 may supply polarized light. The illumination source 344 may include a light source and a beam splitter so that two orthogonal light beams may be supplied, one for each grating, at the incident angle θ_{incident}. The illumination source 344 may include two light sources so that two orthogonal light beams may be supplied, one for each grating, at the incident angle θ_{incident}.

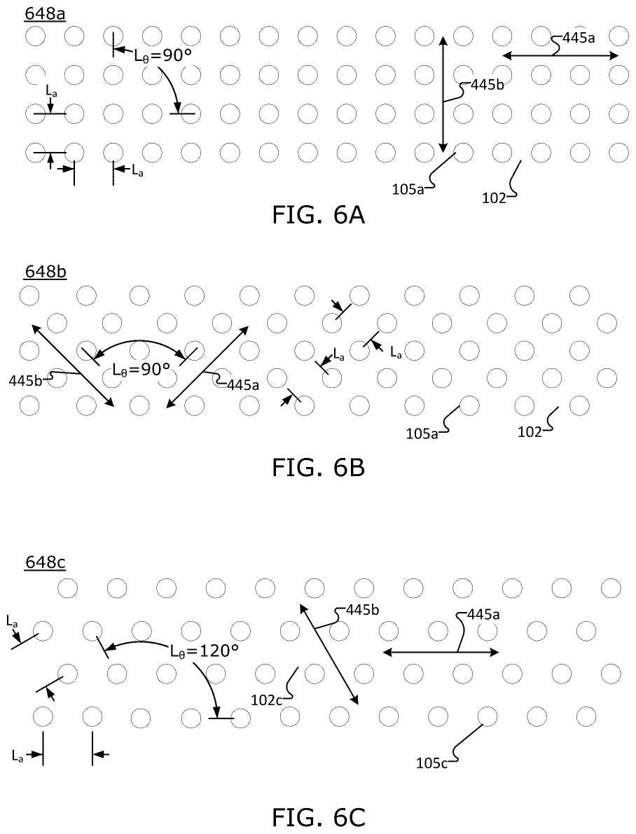

In an embodiment, the illumination light from the illumination source 344 passes through each of the gratings 343, then reflects off the interconnect contacts 105, and then passes through the gratings 343 again forming a moiré pattern as illustrated in FIGS. 6D-F. In an alternative embodiment, the illumination light from the illumination source 344 is reflected by the grating 343, then reflects off the interconnect contacts 105, and then reflects again off the grating 343(a,b,c,d) to form a moiré pattern. An embodiment, may include additional optical components for guiding light between the grating 343(a,b,c,d) and the interconnect contacts 105. The contact pitch p_{contact} is a distance between two neighboring interconnect contacts 105 in a measurement direction. The contact pitch p_{contact} may be 10 μm; 20 μm; 50 μm; 100 μm and may vary between 5 μm and 500 μm. The interconnect contacts 105 are arranged on chip 102 and the substrate 104 in a regular two dimensional pattern and form a pattern that is similar to a binary 2D intensity grating. The moiré pattern will have a moiré pitch p_{moiré} that is dependent upon the grating pitch p_{grating} and a contact pitch p_{contact}. as described in equation (1) below when the measurement is done with a first order diffraction beam. The moiré pattern may also be characterized in terms of a spatial frequency. The pitches have an inverse relationship with the spatial frequency (f=1/p).

$${p}_{moiré} = \frac{{p}_{contacts} {p}_{grating}}{2 \vert {p}_{contacts} - {p}_{grating} \vert} \qquad ( 1 )$$

In an embodiment, the alignment system 300 makes use of two gratings with two different gratings pitches p_{gratings,1} and p_{gratings,2} that produce substantially the same moiré pitch p_{moiré} or as described by equations (2). In an alternative embodiment, the two different gratings don't produce substantially the same moiré pitch p_{moiré}.

$${p}_{moiré} = \frac{{p}_{contacts} {p}_{grating , 1}}{2 ( {p}_{contacts} - {p}_{grating , 1} )} {p}_{grating , 1} < {p}_{contacts} {p}_{moiré} = \frac{{p}_{contacts} {p}_{grating , 2}}{2 ( {p}_{grating , 2} - {p}_{contacts} )} {p}_{grating , 2} > {P}_{contacts} \qquad ( 2 )$$

In order to meet the matching criteria, the gratings are selected based on the contact pitch or frequency and the desired moiré pitch as described in equations (3).

$${p}_{grating , 1} = \frac{2 {p}_{moiré}}{{p}_{contacts} + 2 {p}_{moiré}} {p}_{contacts} {p}_{grating , 1} < {p}_{contacts} {p}_{grating , 2} = \frac{2 {p}_{moiré}}{2 {p}_{moiré} - {p}_{contacts}} {p}_{contacts} {p}_{grating , 2} > {P}_{contacts} \qquad ( 3 )$$

The moiré pitch p_{moiré} is selected to be less than or equal to the width of the chip set of interconnect contacts 105b in the measurement direction. The moiré pitch p_{moiré} may also be selected to be less than a field of view (FOV) of the detection system 346. The detection system 346 may be optimized to work with a limited range of values or a set of specific values for the moiré pitch p_{moiré} such as between 10-300 μm. FIG. 3G is chart showing the relationship between the pitch of both of the gratings (p_{grating,1} and p_{grating,2}) the contact pitch p_{contact} and two different moiré pitches p_{moiré}.

In an embodiment, the alignment system 300 includes a detection system 346 for measuring the moiré pattern. In an embodiment the field of view of the detection is greater than or equal to the moiré pitch p_{moiré}. The detection system 346 includes a sensor and one or more of: a polarizer; a wavelength selective filter; an aperture; lenses; and mirrors. The sensor of the detection system may be: a digital camera; an image sensor; a CCD image sensor; a CMOS image sensor, or any other suitable device for obtaining information about the moiré pattern. The arrangement of the interconnect contacts 105 on the chip 102 and the substrate 104 will act as two dimensional binary amplitude grating in which each of the interconnect contacts 105a will act as a reflector and the array of the reflectors will create an interference pattern in accordance with the simple grating equation in equation (4). An amplitude grating is a device that spatially modulates the intensity of an electromagnetic wavefront. In which, m is an integer {m∈Z} and is the diffracted order of the measurement light reflected by the array of interconnect contacts 105; θ_{incident} is the incident angle on which measurement light from the illumination source 344 is incident on the chip 102; λ is the central wavelength of measurement light; and θ_{diffracted,m} is the angle of the diffracted light of order m.

$$sin ( {θ}_{i n c i d e n t} ) + sin ( {θ}_{diffracted , m} ) = \frac{m λ}{{p}_{c o n t a c t s}} \qquad ( 4 )$$

The gratings 343 will act as a periodic spatial filter but will also diffract the light depending on the orientation of the measurement light relative to the rulings of the gratings 343. If a component of the direction of the measurement light is parallel to the ruling directions as illustrated in FIG. 3E then the gratings 343 will act solely as a periodic spatial filter and the array of interconnect contacts 105 will act like a diffraction grating, masked by the periodic spatial filter. Parallel in the present context means within 0°±5° FIG. 3E illustrates the −1, 0, and +1 diffraction orders produced by the array of interconnect contacts 105.

The detection system 346 measures the plurality of moiré patterns formed by the each of the gratings 343 and the interconnect contacts 105. Each group of gratings 341 will produce a moiré pattern pair. The processor 130 will analyze each of the moiré patterns to determine the location of the interconnect contacts 105 relative to the gratings 343. Analyzing the moiré patterns includes: performing spatial Fourier analysis on each of the moiré patterns; filtering out the spatial high frequency components; and comparing the phase information of the moiré pattern pair. The relative phase information is correlated with the relative location of the interconnect contacts with each group of gratings. In an embodiment, only one grating is used for each direction.

### Interconnect Contacts

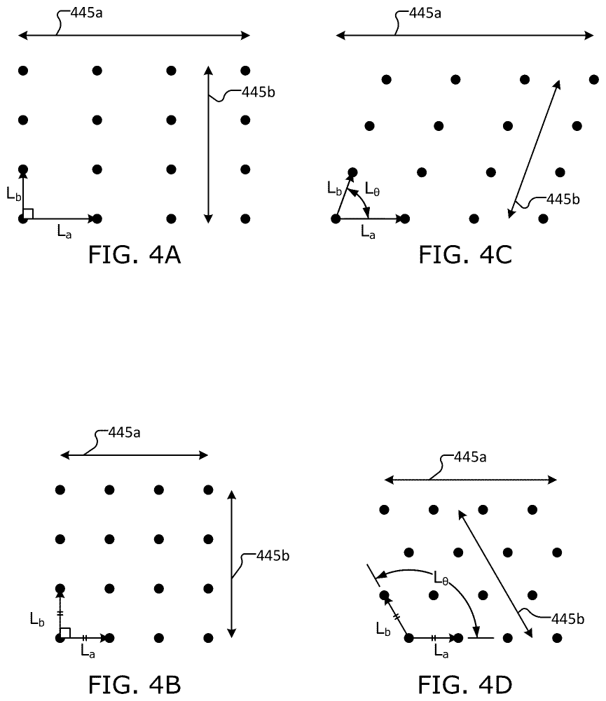

The chip 102 and the substrate 104 both includes a set of interconnect contacts 105. The set of interconnect contacts 105 are arranged on a lattice across a bonding surface of the chip 102 and the bonding surface of the substrate 104. There are a variety of different lattices that the chips and the substrate may be arranged on the chip. These different lattices may be characterized by a lattice type and a plurality of lattice dimensions. The two dimensional lattice types that are applicable to a set of interconnect contacts 105 fall into two broad types: rectangular and oblique. Rectangular lattices have lattice points at regular intervals into two orthogonal lattice directions 445 as illustrated in FIG. 4A. The lattice parameters of a rectangular lattice are a lattice distance Lₐ between each lattice point in a first lattice direction 445a and a lattice distance L_{b} in an orthogonal second lattice direction 445b. A subset of rectangular lattices are square lattices in which Lₐ is equal to L_{b} as illustrated in FIG. 4B. Oblique lattices have lattice points at regular intervals into two non-orthogonal directions 445 as illustrated in FIG. 4C. The lattice parameters of an oblique lattice are a lattice distance Lₐ between each lattice point in a first lattice direction 445a and a lattice distance L_{b} in a second lattice direction 445b and a lattice angle L_{θ} between the first lattice direction 445a and second lattice direction 445b. A subset of oblique lattices are hexagonal lattices in which Lₐ is equal to L_{b} and L_{θ} is 120° or 60° as illustrated in FIG. 4D.

The typically chip 102 and substrate 104 will be laid out in either square or hexagonal lattice type. The interconnect contacts 105 are laid out in a hexagonal lattice have the highest density and interconnect contacts 105 laid out in a square lattice have the simplest layout. The applicant has found that the measurement directions depend on the lattice type and gratings need to be oriented in different directions relative to the chip depending on the lattice type and the lattice directions.

### Bonding Method

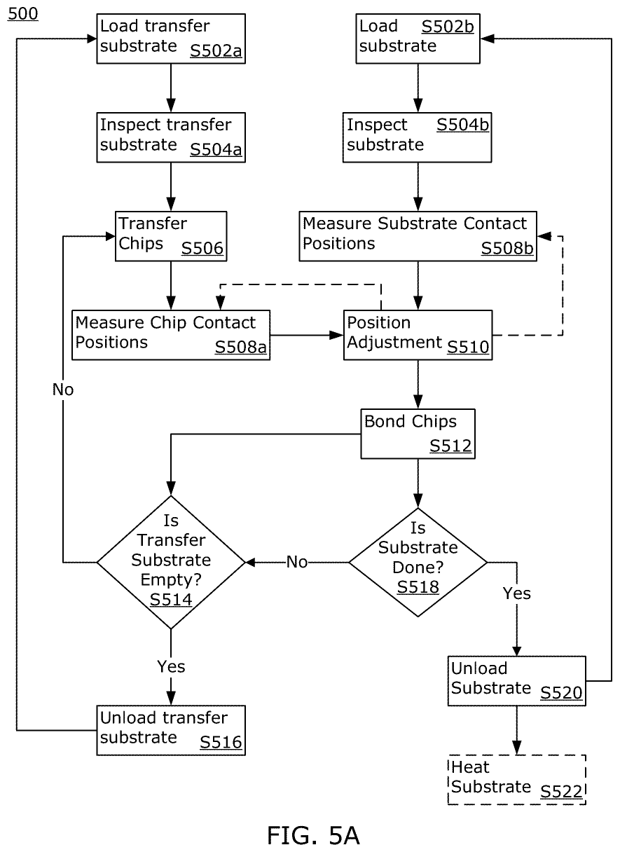

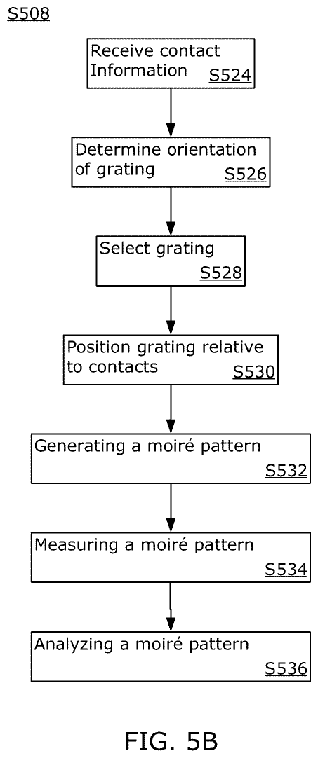

The bonding system 100 is used to bond a plurality of chips 102 onto a plurality of substrates 102 using a bonding method 500 illustrated in FIG. 5A. Prior to the bonding method 500 being performed registration steps may be performed in which the substrate stage 114, the upward facing alignment system 124a, and the downward facing alignment system 124b are registered with each other. The bonding method 500 may include loading a transfer substrate 106 onto the transfer chuck 110 in a first loading step S502a. The bonding method 500 may include loading a substrate 104 onto the substrate chuck 104 in a second loading step S502b. One or more robots may be used in the loading steps S502(a,b). The one or more robots may be a wafer handling robot. The robot may be a chip feeding system or tray handler. The second loading step S502b may include standard lithography alignment techniques using standard alignment techniques and using alignment marks such as: moiré interference marks; one or more two-dimensional diffraction gratings; crosses, box in box, bar-in-bars, bullseyes, edge marks, serpentine marks, etc.

The bonding method 500 may include a first inspection step S504a of obtaining pictures of the transfer substrate S504a with an upward facing microscope 126. The upward facing microscope 126 may obtain pictures of the transfer substrate 106 and the processors 130 will analyze those pictures to identify positions of the chips 102 on the transfer substrate 106. The bonding method 500 may include a second inspection step S504b of taking pictures of the substrate 106 with a downward facing microscope 128. The upward facing microscope 128 may obtain pictures of the substrate 104 and the processors 130 will analyze those pictures to identify bonding positions on the substrate 104. The tilt of the substrate 104 on the substrate chuck 108 may also be measured.

The bonding method 500 may include a transfer step S506 in which one or more transfer heads 120 may transfer chips 102 from the transfer substrate 106 to the one or more bonding heads 122. The transfer step may be done with an accuracy that is within the range of a bonding head chip stage 222b. In an alternative embodiment, the one or more bonding heads 122 retrieve one or more chips 102 directly from the transfer substrate 106. The approximate position of the chip on the bonding head may be measured using the upward facing microscope 126. The upward facing microscope 126 may be a high NA microscope that is able to resolve marks around 3 μm at the corners of the chip 102.

The bonding method 500 may include a chip contacts position measuring step S508a in which the upward facing alignment system 124a measures the positions of the chip set of interconnect contacts 105a on each chip 102 relative to the bonding head chip chuck 222a on which it is mounted which is transmitted to the processors 130. The bonding method 500 may include a substrate contacts position measuring step S508b in which the downward facing alignment system 124b measures the positions of the substrate set of interconnect contacts 105b on the substrate relative to the substrate chuck 108 which is transmitted to the processors 130. In an alternative embodiment, a single alignment system 124 is used for measuring the chip set of interconnect contacts 105a on a chip 102 and substrate set of interconnect contacts 105b on the substrate 104, by having optics that guide light to and from the chip 102 and the substrate 104. In an embodiment, the substrate 102 has a plurality of bonding positions which are determined by the downward facing microscope and/or information received by the processors 130 about the substrate 104.

The bonding method 500 may include a position adjustment step S510. The position adjustment step S510 includes processors 130 sending instructions to one or more bonding head chip stages 222b and/or the substrate stage 114 based on the alignment information gathered in the chip contacts position measuring step S508a; the substrate contacts position measuring step S508b; and information about the expected bonding position of each of the chips. The expected bonding position information on the substrate may be obtained from the downward facing microscope or from information about the substrate 104 obtained by the processor from a database or a message from another processor on a network. The substrate stage 14 may include a stage position encoder that allows accurate positioning of the substrate relative to the bonding heads 122. The stage position encoder may be: a laser optical interferometer position measurement system; an ultrasonic distance measurement system; a capacitive displacement measurement system; optical position encoders; and other methods of measuring the position of an object with sub-micron resolution. Each of the bonding head stages 222b may include a bonding head position encoder that is similar to the stage position encoder. In an embodiment, the contact measurement steps S508(a,b) may be performed again after the position adjustment step S510, these steps may be repeated until the measurements are within an alignment threshold. In an alternative embodiment, the contact measurement steps S508(a,b) are performed only once for each bonding step.

The bonding method 500 may include a bonding step S512 in which one or more bonding heads 122 are brought towards the substrate chuck 108. Each of the bonding head chip stages 222b may include one or more actuators which move each bonding head chip chuck 222a towards the substrate chuck 110 until each chip 102 held by a bonding head touches the substrate 104. The bonding step S512 is the step in which the die is brought into contact with the substrate by the bonding head and is just one part of an overall bonding process.

If the bonding method 500 is a hybrid bonding method, then the bonding surfaces of the chip 102 with the substrate 104 are activated prior to the bonding step S512. The bonding surfaces of the chips 102 may be activated while the chips are on the bonding heads 122. The bonding surfaces of the chips 102 may be activated while the chips are on the transfer heads 120. The bonding surfaces of the chips 102 may be activated while the chips are on the transfer substrate 106 while it is on the transfer chuck 110. The bonding surfaces of the chips 102 may be activated while the chips are on the transfer substrate 106 while it is on the transfer chuck 110. The bonding surfaces of the chips 102 may be activated prior to the first loading step S502a. The bonding surface of the substrate 104 may be activated while the substrate 104 is on the substrate chuck 108. The bonding surface of the substrate 104 may be activated prior to the second loading step S502b.

Activating the bonding surfaces may include rinsing the bonding surfaces with deionized water and exposing the bonding surfaces to a plasma. Other well known methods may be used for preparing the bonding surfaces so that dangling bonds are created on the bonding surfaces.

After the bonding step S512, the transfer substrate may be checked in a transfer substrate checking step S514. The transfer substrate checking step S514 may include the processor 130 checking information about the transfer substrate 106 in memory 132 to determine how many chips 102 were on the transfer substrate 106 that were to be bonded and how many were removed in subsequent transfer steps. If the answer is yes and the transfer substrate is empty of chips that are to be transferred, then the processor 130 will send instructions for the transfer substrate to be removed from the bonding system 100 in a first unloading step S516. After the first unloading step S516 the bonding process 500 returns to first loading step S502a unless there are no more chips to be bonded in which case the bonding method 500 ends. If the transfer substrate 106 is not empty of chips to be bonded, then the bonding method 500 returns to transfer step S506.

Also after the bonding step S512 the substrate 102 is checked in a substrate checking step S518. The substrate checking step S518 may include the processor 130 checking information about the substrate 104 in memory 132 to determine how many bonding locations were on the substrate 104 that were to be bonded to and how many of those bonding locations already have chips bonded to them in bonding step S512. If the answer is yes and there are no more empty bonding locations, then the processor 130 will send instructions for the substrate 104 to be removed from the bonding system 100 in a second unloading step S520. After the second unloading step S520 the bonding process 500 returns to second loading step S502n unless there are no more chips to be bonded in which case the bonding method 500 ends.

After the second unloading step S520, if the substrate is being bonding with a hybrid bonding method, then the substrate 104 is subjected to a heating step S522. During the heating step S522 the substrate is heat which causes the metal interconnect contacts 105 to expand relative to the bonding surface forming electrical connections between the chips 102 and the substrate 104. The heating step S522 may be performed at 200° C. to 300° C. In an embodiment, the heating step S522 may be performed at a higher temperature than the bonding step S512. The product substrate may then be subjected to additional bonding method 500 to attach additional chips to the substrate. After the heating step S522 the substrate may be subjected to additional semiconductor processing steps, such as: singulation, testing, encapsulation, etc., which are used to produce a plurality of articles from the substrate.

### Alignment Method

The contacts position measuring step S508a and the substrate contacts position measuring step S508b may be done using the same contacts measuring step S508 the details of which are described in FIG. 5B. The contacts measuring step S508 may include a receiving step S524 in which the processors 130 receive contacts information about the arrangement of interconnect contacts 105 on the chip 102 and the substrate 104. The contacts information may include: a pitch in a first direction Lₐ; and a lattice type. The contacts information may also include: a pitch in a second direction L_{b}; and a lattice angle L_{θ}. FIGS. 6A-B are illustrations of a first portion 648a and a second portion 648b of interconnect contacts 105a of a chip 102 showing the lattice directions 445 for each portion 648. The contacts information for chip 102 includes: a square type lattice; a pitch in a first direction Lₐ; that same pitch in a second direction Lₐ; and a lattice angle L_{θ} of 90° showing the lattice directions 445. FIG. 6C is an illustration of a third portion 648c of interconnect contacts 105c of a chip 102c. The contacts information for a second chip 102c includes: a hexagon type lattice; a pitch in a first direction Lₐ; that same pitch in a second direction Lₐ; and a lattice angle L_{θ} of 120°. Some of the lattice points in FIGS. 6A-6B have been removed to aid understanding.

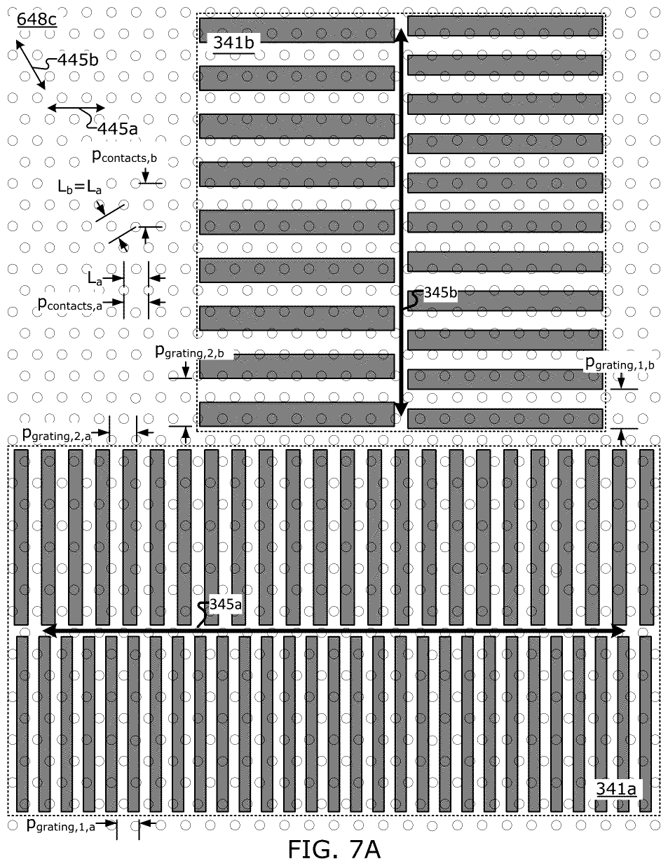

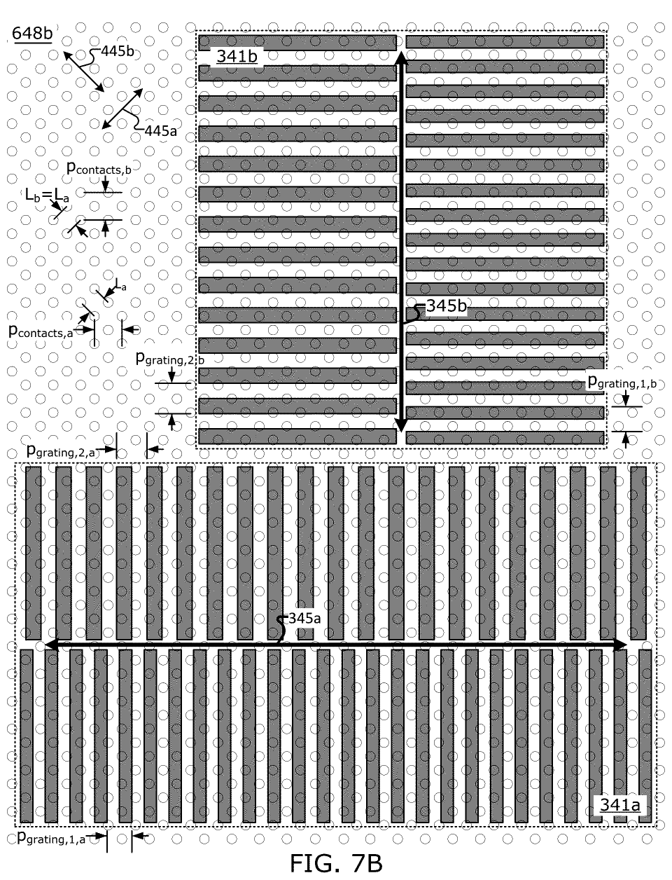

The contacts measuring step S508 may include a grating orientation selection step S526. The grating orientation selection step S526 may include the processor 130 determining how the gratings are to be oriented relative to the interconnect contacts 105 based on the contact information for example the lattice type. The processor 130 may include determining that the orientation of the pitch of the first group of gratings 341a as parallel to one of the grating lattice directions (for example first lattice direction 445a) if the lattice type is oblique (for example hexagonal) and the pitch of the second group of gratings 341b as orthogonal to the first group of gratings 341a as illustrated in FIG. 7A. The processor 130 may include determining that the orientation of the pitches of both the first group of gratings 341a and the second group of gratings 3410 at an angle greater than 0° and less than 90° for example 45° relative to both of the first lattice direction 445a and the second lattice direction 445b if the lattice type is rectangular (for example square) as illustrated in FIG. 7B. An orientation angle of the pitch of the first group of gratings 341a may be determined based on the lattice information of the interconnect contacts 105. An orientation angle of the pitch of the second group of gratings 341b may be determined based on the lattice information of the interconnect contacts 105 and orientation angle of the pitch.

The contacts measuring step S508 may include a grating selection step S528. The grating selection step S528 may include the processor 130 selecting a first group of gratings 341a based on the contacts information for example the pitch in a first direction Lₐ. The bonding system 100 includes a library of gratings with different pitches. The detection system is designed to work with a range of moiré pitches p_{moiré} between an upper limit moiré pitch p_{m,UL} and a lower limit moiré pitch p_{m,LL} as described in equation (5). Examples of the upper limit moiré pitch p_{m,UL} is 500 μm, 450 μm, 300 μm, 150 μm, 100 μm or a value that is determined by the optical design and desired alignment accuracy. Examples of the lower limit moiré pitch p_{m,LL} is 30 μm, 50 μm, 100 μm, 150 μm, or a value that is determined by the optical design and desired alignment accuracy.

$${p}_{m , LL} \leq {p}_{moiré} \leq {p}_{m , UL} \qquad ( 5 )$$

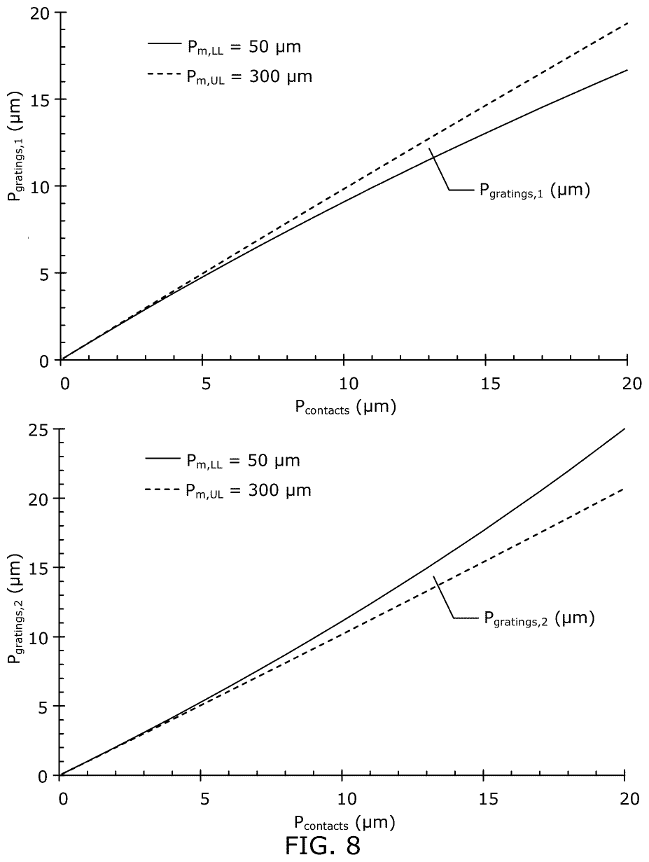

The processor 130 may then select the two pairs of grating pitches p_{grating,1,a} and p_{grating,2,a} and p_{grating,1,b} and p_{grating,2,b} based on the limits of the detection system and the contact information as described in equations (6) below and illustrated in FIG. 8.

$$\frac{2 {p}_{m , LL} {p}_{contacts , a}}{{p}_{contacts , a} + 2 {p}_{m , LL}} \geq {p}_{grating , 1 , a} \geq \frac{2 {p}_{m , UL} {p}_{contacts , a}}{{p}_{contacts , a} + 2 {p}_{m , UL}} \\ {p}_{grating , 1 , a} < {p}_{contacts , a} \frac{2 {p}_{m , UL} {p}_{contacts , a}}{2 {p}_{m , UL} - {p}_{contacts , a}} \geq {p}_{grating , 2 , a} \geq \frac{2 {p}_{m , LL} {p}_{contacts , a}}{2 {p}_{m , LL} - {p}_{contacts , a}} \\ {p}_{grating , 2 , a} > {p}_{contacts , a} \frac{2 {p}_{m , LL} {p}_{contacts , b}}{{p}_{contacts , b} + 2 {p}_{m , LL}} \geq {p}_{grating , 1 , b} \geq \frac{2 {p}_{m , UL} {p}_{contacts , b}}{{p}_{contacts , b} + 2 {p}_{m , UL}} \\ {p}_{grating , 1 , b} < {p}_{contacts , a} \frac{2 {p}_{m , UL} {p}_{contacts , b}}{2 {p}_{m , UL} - {p}_{contacts , b}} \geq {p}_{grating , 2 , b} \geq \frac{2 {p}_{m , LL} {p}_{contacts , b}}{2 {p}_{m , LL} - {p}_{contacts , b}} \\ {p}_{grating , 2 , b} > {p}_{contacts , a} \qquad ( 6 )$$

Selecting the two pairs of grating pitches includes determining the contact pitches p_{contacts,a} and p_{contacts,b} and based on a process represented by equation (7) below. FIGS. 7A-B illustrate how the contact pitches p_{contacts,a} and p_{contacts,b} that are relevant to the equations above. First the grating pitch directions 345(a,b) of each of the gratings is determined in the grating orientation selection step S526 describe above. The grating orientation selection step S526 is performed such that at least one direction has a staggered array of contacts as illustrated in FIGS. 7A-B. For each grating 341(a,b), the contact pitches p_{contacts,(a,b)} is the distance between contacts in a single line in the grating pitch directions 345(a, b) as illustrated in FIGS. 7A-B. FIG. 7A is oblique lattice type, FIG. 7B is a rectangular lattice type.

$${P}_{contacts , a} = {f}_{a} ( {L}_{a} , {L}_{b} , {L}_{θ} , lattice type ) {P}_{c o n tacts , b} = {f}_{b} ( {L}_{a} , {L}_{b} , {L}_{θ} , lattice type ) \qquad ( 7 )$$

The contacts measuring step S508 may include a grating positioning step S530. The grating positioning step S530 may include positioning the selected grating at the selected orientation relative to the interconnect contacts 105. The processor 130 may send instructions to the grating positioning system 342 to position a grating set relative to the interconnect contacts 105 to be measured. The processor 130 may send instructions to load two or more gratings onto the grating set carrier. The loading may be performed by one or more linked actuators configured to move an end effector adapted for handling the gratings. In an embodiment, the grating set carrier 338 may include multiple sets of gratings. The grating positioning system 342 may include a plurality of actuators and encoders configured to move and rotate the gratings relative to the interconnect contacts 105. The grating positioning step S530 may include registering the grating set 340 with one or both of the upward facing microscope 126 and the downward facing microscope 128 relative to the bonding head 122 and substrate chuck 108. The grating positioning step S530 may include positioning grating set 340 within 10 μm of the chip 102 on the bonding head 122.

The contacts measuring step S508 includes a moiré pattern generating step S532. The moiré pattern generating step S532 may include sending measurement light towards a grating 343 in the grating set 340. In an embodiment, the grating is a binary amplitude transmission grating and the light passes through the grating towards the interconnect contacts 105, which is then reflected and diffracted back at the grating passing through the grating to generate a moiré pattern. In second embodiment, the grating is a binary amplitude reflection grating and the light is reflected and diffracted by the grating towards the interconnect contacts 105, which is then reflected and diffracted back at the grating passing through the grating to generate a moiré pattern. In a third embodiment, the grating is a phase transmission grating and the light is diffracted by the grating towards the interconnect contacts 105, which is then reflected and diffracted back at the grating and diffracted again by the grating to generate a moiré pattern. In fourth embodiment, the grating is a phase reflection grating and the light is reflected and diffracted by the grating towards the interconnect contacts 105, which is then reflected and diffracted back at the grating and reflected and diffracted by the grating to generate a moiré pattern.

The contacts measuring step S508 includes a moiré pattern measuring step S532. The moiré pattern measuring step S532 includes gathering light from the grating with the detection system 346. The detection system 346 will then send the information about the moiré pattern to the processors 130.

The contacts measuring step S508 includes a moiré pattern analyzing step S534. The moiré pattern analyzing step S534 includes the processor 130 analyzing the moiré pattern to determine the relative position of the grating 343 to the set of interconnect contacts 105. Analyzing the moiré pattern includes performing a spatial Fourier transform either optically or analytically of a spatial intensity of a moiré pattern produces from the contacts and the gratings, a comparison of the phase values can then be converted into relative position of the gratings to the contacts using known methods. An example of such a method is described in E. E. MOON, Mask-substrate alignment via interferometric moiré fringes, Nanolithography, The Art of Fabricating Nanoelectronic and Nanophotonic Devices and Systems, pages 466-502, Edited by Martin FELDMAN, Woodhead Publishing Limited, Cambridge, UK, 2014, which is hereby incorporated by reference.

### Moiré Pattern

The moiré pattern generating step S532 generates a plurality of moiré patterns based on the interconnect contacts 105 and the grating set 340. FIG. 6A is an illustration of a first portion 648a of a chip set of interconnect contacts 105a that are round with a diameter of 5 μm have a pitch in a first direction Lₐ and a pitch in a second direction L_{b} that are 10 μm, the lattice angle L_{θ} is 90°, and the lattice type is rectangular. FIG. 6A is an illustration of a second portion 648b of the same chip set of interconnect contacts 105a except it is oriented at 45° relative to the first portion 648a illustrated in FIG. 6A. FIG. 6C is an illustration of a third portion 648c of a chip set of interconnect contacts 105a that are round with a diameter of 5 μm have a pitch in a first direction Lₐ and a pitch in a second direction L_{b} that are 10 μm, the lattice angle L_{θ} is 120°, and the lattice type is oblique. FIG. 7A is an illustration of the overlapping interconnect contacts 105 on an oblique lattice type and a grating set. FIG. 7B is an illustration of the overlapping interconnect contacts 105 on an rectangular lattice type and a grating set.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method comprising:
holding a chip on a chip chuck, wherein the chip has a set of interconnect contacts;
positioning a first grating relative to the set of interconnect contacts;
measuring a first moiré pattern of the first grating and the set of interconnect contacts; and
adjusting position of the chip chuck relative to a substrate chuck based on the first moiré pattern.

2. The method of claim 1, wherein the first grating has a grating pitch that is different from a contact pitch of the set of interconnect contacts.

3. The method of claim 1, further comprising:
receiving contact arrangement information about the set of interconnect contacts; and
selecting the first grating from a group of gratings with different pitches based on the contact arrangement information.

4. The method of claim 3, wherein the selecting the grating includes:
determining a lattice type of the set of interconnect contacts based on the contact arrangement information;
determining two measurement directions based on the lattice type; and
determining two contact pad pitches, each contact pad pitch based on distances between neighboring contact pads in a measurement direction from among the two measurement directions.

5. The method of claim 4, wherein the two measurement directions are orthogonal to each other.

6. The method of claim 4, wherein the lattice type is rectangular and one of the two measurement directions is an inverse tangent of a ratio of contact pad pitches in each lattice direction of the set of interconnect contacts.

7. The method of claim 4, wherein the lattice type is oblique and a measurement the measurement direction is parallel to a lattice direction of the set of interconnect contacts.

8. The method of claim 1, wherein measuring the first moiré pattern comprises:
illuminating the first grating at an angle relative to a plane of the first grating in a direction that is parallel to rulings of the first grating with measurement radiation; and
measuring the measurement radiation that has diffracted off the set of interconnect contacts.

9. The method of claim 1, wherein positioning a grating comprises:
orienting rulings of the first grating relative to set of interconnect contacts based on a lattice type of the set of interconnect contacts.

10. The method of claim 1, wherein adjusting the position of the chip chuck comprises:
sending an instruction to a chip chuck stage to adjust the position of chip chuck relative to the substrate chuck.

11. The method of claim 1, further comprising:
positioning a substrate grating relative to the substrate chuck holding a substrate, wherein the substrate has a second set of interconnect contacts; and
measuring a substrate moiré pattern of the substrate grating and the substrate set of interconnect contacts; and
wherein the position of the chip chuck is adjusted based on both the moiré pattern and the substrate moiré pattern.

12. The method of claim 11, wherein the first grating is identical to the substrate grating.

13. The method of claim 1, further comprising:
positioning a second grating relative to the set of interconnect contacts;
wherein a first set of rulings of the first grating are oriented in a different direction than a second set of rulings of the second grating; and
measuring a second moiré pattern of the second grating and the set of interconnect contacts; and
wherein the adjusting position of the chip chuck relative to the substrate chuck is based on the first moiré pattern and the second moiré pattern.

14. The method of claim 1, further comprising:
bonding the chip to product substrate; and
processing the substrate to manufacture a plurality of articles.

15. The method claim 1, wherein the measuring and the adjusting are done repeatedly until the set of interconnect contacts are in a desired position based on the first moiré pattern.

16. A bonding system controller, wherein the bonding system controller is adapted to:
send instructions to a chip chuck to hold a chip, wherein the chip has a set of interconnect pads;
send instructions to a grating positioning system configured to position a first grating relative to the set of interconnect contacts;
receive a first moiré pattern of the first grating and the set of interconnect contacts from a measurement system; and
send instruction of a chip chuck positioning system configured to adjust the position of the chip chuck relative to the wafer chuck based on the first moiré pattern.

17. A bonding system for bonding a chip that has a set of interconnect contacts to a substrate comprising:
a chip chuck configured to hold the chip;
a wafer chuck configured to hold the substrate;
a grating positioning system configured to position a first grating relative to the set of interconnect contacts;
a measuring system configured to measure a first moiré pattern of the first grating and the set of interconnect contacts; and
a chip chuck positioning system configured to adjust the position of the chip chuck relative to the wafer chuck.

18. The bonding system of claim 17, wherein the chip chuck positioning system is further configured to bring the chip into contact with the substrate.

19. The bonding system of claim 17 further comprising:
a plurality of gratings with different pitches; and
a selection tool for selecting one of the plurality of gratings based on a pitch of the set of interconnect contacts.

20. The bonding system further comprising:
a measurement positioning system configured to adjust positions of one or both of an illumination system and a measurement system based on arrangement information of the set of interconnect contacts.
